(19) United States
(12) Patent Application Publication
(10) Pub. No.: US 2022/0356584 A1
(43) Pub. Date: Nov. 10, 2022

(54) SUBSTRATE PROCESSING METHOD AND SUBSTRATE PROCESSING APPARATUS

(71) Applicant: Tokyo Electron Limited, Tokyo (JP)

(72) Inventor: Maju TOMURA, Miyagi (JP)

(21) Appl. No.: 17/736,048

(22) Filed: May 3, 2022

(30) Foreign Application Priority Data
May 7, 2021 (JP) 2021-078865

(51) Int. Cl. C23F 1/08; C23F 1/12

(52) U.S. Cl. CPC C23F 1/08; C23F 1/12

(57) ABSTRACT

In one exemplary embodiment, a substrate processing apparatus is provided. The substrate processing apparatus comprises: a chamber; a substrate support disposed in the chamber; a gas supply disposed in the chamber and connected to a supply source of reaction gas containing HF gas and CₓH_{y}F_{z} gas (where x and z are integers equal to or greater than 1 and y is an integer equal to or greater than 0); and a plasma-generator configured to form a plasma from the reaction gas supplied to the chamber from the gas supply, wherein at least a portion of the chamber exposed to the plasma is made of a conductive silicon-containing material.

### BACKGROUND

Exemplary embodiments of the present disclosure relate to a substrate processing method and a substrate processing apparatus.

### RELATED ART

Patent Document 1 discloses a technique for coating the interior of a chamber for plasma processing.

### CITATION LIST

### Patent Literature

[Patent Document 1] JP 2016-208034 A

### SUMMARY

In one exemplary embodiment of the present disclosure, a substrate processing apparatus is provided, in which the substrate processing apparatus comprises: a chamber; a substrate support disposed in the chamber; a gas supply disposed in the chamber and connected to a supply source of reaction gas containing HF gas and CₓH_{y}F_{z} gas (where x and z are integers equal to or greater than 1 and y is an integer equal to or greater than 0); and a plasma-generator configured to form a plasma from the reaction gas supplied to the chamber from the gas supply, wherein at least a portion of the chamber exposed to the plasma is made of a conductive silicon-containing material.

### BRIEF DESCRIPTION OF THE DRAWINGS

FIG. 1 is a figure schematically illustrating a substrate processing apparatus 1.

FIG. 2 is a figure showing an example of the cross-sectional structure of a chamber body 12.

FIG. 3 is a figure showing an example of the cross-sectional structure of a substrate W.

FIG. 4 is a flowchart showing an example of the processing method.

FIG. 5 is a figure showing examples of the shape of a mask film MK after etching.

FIG. 6 is a figure showing an example of the cross-sectional structure of a substrate W in step ST3.

### DETAILED DESCRIPTION

Embodiments of the present disclosure will now be described.

In an exemplary embodiment, a substrate processing apparatus is provided. The substrate processing apparatus comprises: a chamber; a substrate support disposed in the chamber; a gas supply disposed in the chamber and connected to a supply source of reaction gas containing HF gas and CₓH_{y}F_{z} gas (where x and z are integers equal to or greater than 1 and y is an integer equal to or greater than 0); and a plasma-generator configured to form a plasma from the reaction gas supplied to the chamber from the gas supply, wherein at least a portion of the chamber exposed to the plasma is made of a conductive silicon-containing material.

In an exemplary embodiment, wherein the flow rate of the CₓH_{y}F_{z} gas supplied to the chamber is 5 vol % or more relative to the overall flow rate of the reaction gas.

In an exemplary embodiment, an inner wall of the chamber is configured by applying a liner made of a conductive silicon-containing material.

An exemplary embodiment further comprises an upper electrode arranged facing the substrate support, wherein the upper electrode has the gas supply.

In an exemplary embodiment, the upper electrode comprises a top plate having a plurality of gas discharge holes for supplying the reaction gas to the chamber, and the top plate is made of a conductive silicon material.

An exemplary embodiment comprises a power source for supplying negative direct current voltage or low RF power to the chamber.

An exemplary embodiment comprises a power source for supplying negative direct current voltage or low RF power to the upper electrode.

In an exemplary embodiment, a side wall constituting the chamber has the gas supply.

In an exemplary embodiment, a substrate processing method is provided. The substrate processing method comprises the steps of: preparing a substrate comprising a silicon-containing film on a substrate support disposed in a chamber; supplying a reaction gas containing HF gas and CₓH_{y}F_{z} gas (where x and z are integers equal to or greater than 1 and y is an integer equal to or greater than 0) to the chamber; and forming plasma from the reaction gas supplied to the chamber in order to etch the silicon-containing film, wherein at least a portion of the chamber exposed to the plasma is made of a conductive silicon-containing material.

In an exemplary embodiment, the flow rate of the CₓH_{y}F_{z} gas is 5 vol % or more relative to the overall flow rate of the reaction gas.

In an exemplary embodiment, an inner wall of the chamber is configured by applying a liner made of a conductive silicon-containing material.

In an exemplary embodiment, negative direct current voltage or low RF power is supplied to the chamber in the step of forming plasma.

In an exemplary embodiment, a side wall constituting the chamber has a gas supply that supplies the reaction gas to the chamber.

In an exemplary embodiment, an upper electrode arranged facing the substrate support is further provided, the upper electrode having a gas supply that supplies the reaction gas to the chamber.

In an exemplary embodiment, the upper electrode comprises a top plate having a plurality of gas discharge holes for supplying the reaction gas to the chamber, and the top plate is made of a conductive silicon material.

In an exemplary embodiment, negative direct current voltage or low RF power is supplied to the upper electrode in the step of forming plasma.

In an exemplary embodiment, the CₓH_{y}F_{z} gas is at least one type selected from the group consisting of C₄H₂F₆ gas, C₄H₂F₆ gas, C₃H₂F₄ gas, and C₃H₂F₆ gas.

In an exemplary embodiment, the reaction gas further comprises at least one type selected from the group consisting of phosphorus-containing gases, halogen-containing gases, oxygen-containing gases, and nitrogen-containing gases.

The following is a detailed description of embodiments of the present disclosure with reference to the drawings. In the drawings, identical or similar elements are denoted by the same reference numbers and redundant descriptions of these elements has been omitted. In the following description, positional relationships such as up, down, left and right are based on the positional relationships shown in the drawings except where otherwise specified. The dimensional ratios in the drawings do not indicate actual ratios, and the actual ratios are not limited to the ratios shown in the drawings.

### <Configuration of Substrate Processing Apparatus 1>

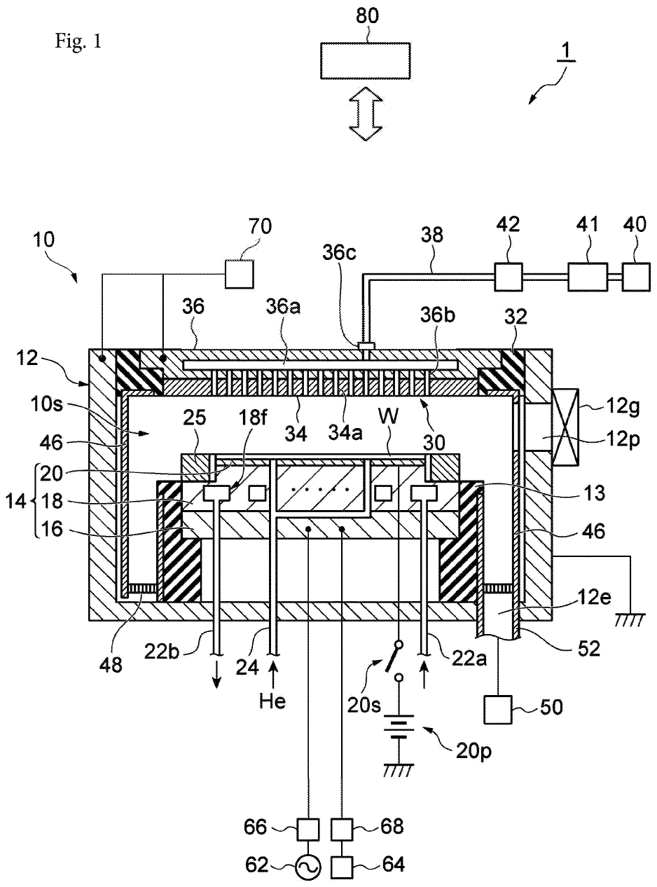

FIG. 1 is a figure schematically illustrating a substrate processing apparatus 1 in an exemplary embodiment. The substrate processing apparatus 1 shown in FIG. 1 includes a chamber 10. The chamber 10 provides an interior space 10s. The chamber 10 includes a chamber body 12. The chamber body 12 has a substantially cylindrical shape.

A passage 12p is formed in the side wall of the chamber body 12. Substrates W are transported between the interior space 10s and the exterior of the chamber 10 via the passage 12p. The passage 12p is opened and closed by a gate valve 12g. The gate valve 12g is provided along the side wall of the chamber body 12.

A support 13 is provided on the bottom of the chamber body 12. This support 13 is formed from an insulating material. The support 13 has a substantially cylindrical shape. The support 13 extends upward from the bottom of the chamber body 12 in the interior space 10s. The support 13 supports a substrate support 14. The substrate support 14 is configured to support a substrate W in the interior space 10s.

The substrate support 14 has a lower electrode 18 and an electrostatic chuck 20. The substrate support 14 may also include an electrode plate 16. The electrode plate 16 is made of a conductor such as aluminum and has a substantially disk shape. A lower electrode 18 is provided on the electrode plate 16. The lower electrode 18 is formed from a conductor such as aluminum and has a substantially disk shape. The lower electrode 18 is connected electrically to the electrode plate 16.

An electrostatic chuck 20 is provided on the lower electrode 18. A substrate W is placed on the upper surface of the electrostatic chuck 20. The electrostatic chuck 20 has a main body and electrodes. The main body of the electrostatic chuck 20 is substantially disk shaped and is formed from a dielectric material. The electrodes for the electrostatic chuck 20 are film-like electrodes, and are provided in the main body of the electrostatic chuck 20. The electrodes of the electrostatic chuck 20 are connected to a direct current power supply 20p via a switch 20s. When voltage from the direct current power supply 20p is applied to the electrodes of the electrostatic chuck 20, an electrostatic attractive force is generated between the electrostatic chuck 20 and the substrate W. A substrate W is attracted to the electrostatic chuck 20 by electrostatic attraction and is held in place by the electrostatic chuck 20.

An edge ring 25 is arranged on the substrate support 14. The edge ring 25 is a ring-shaped member. The edge ring 25 may be formed from, for example, silicon, silicon carbide, or quartz. A substrate W is placed on the electrostatic chuck 20 in the region surrounded by the edge ring 25.

A flow path 18f is provided in the lower electrode 18. A heat exchange medium (for example, a refrigerant) is supplied to the flow path 18f from a chiller provided outside of the chamber 10 via a pipe 22a. The heat exchange medium supplied to the flow path 18f is returned to the chiller via the pipe 22b. In the substrate processing apparatus 1, the temperature of the substrate W placed on the electrostatic chuck 20 is adjusted by heat exchange between the heat exchange medium and the lower electrode 18.

The substrate processing apparatus 1 is provided with a gas supply line 24. The gas supply line 24 supplies heat transfer gas (for example, He gas) from a heat transfer gas supply mechanism to the gap between the upper surface of the electrostatic chuck 20 and the rear surface of the substrate W.

The substrate processing apparatus 1 also includes an upper electrode 30. The upper electrode 30 is provided above the substrate support 14. The upper electrode 30 is supported on the upper portion of the chamber body 12 via a member 32. The member 32 is formed from nine insulating materials. The upper electrode 30 and the member 32 close the upper opening in the chamber body 12.

The upper electrode 30 may include a top plate 34 and a support 36. The lower surface of the top plate 34 is the lower surface on the interior space 10s side, and defines the interior space 10s. The top plate 34 has a plurality of gas discharge holes 34a that pass through the top plate 34 in the thickness direction of the plate.

The support 36 detachably supports the top plate 34. The support 36 is formed from a conductive material such as aluminum. A gas diffusion chamber 36a is provided in the support 36. The support 36 has a plurality of gas holes 36b extending downward from the gas diffusion chamber 36a. The gas holes 36b communicate with the gas discharge holes 34a. A gas inlet 36c is formed in the support 36. The gas inlet 36c is connected to the gas diffusion chamber 36a. A gas supply pipe 38 is connected to the gas inlet 36c.

A group of gas sources 40 is connected to the gas supply pipe 38 via a group of flow rate controllers 41 and a group of valves 42. The gas supply pipe 38, the group of flow rate controllers 41, and the group of valves 42 constitute a gas supply. The gas supply may also include the group of gas sources 40. The group of gas sources 40 includes a plurality of gas sources. The plurality of gas sources include the sources of the processing gases. The group of gas sources 40 includes at least sources of HF gas and CₓH_{y}F_{z} gas (where x and z are integers equal to or greater than 1 and y is an integer equal to or greater than 0). The group of flow rate controllers 41 includes a plurality of flow rate controllers. Each of the plurality of flow rate controllers in the group of flow rate controllers 41 is a mass flow controller or a pressure control-type flow rate controller. The group of valves 42 includes a plurality of opening and closing valves. Each of the plurality of gas sources in the group of gas sources 40 is connected to the gas supply pipe 38 via a corresponding flow rate controller in the group of flow rate controllers 41 and an opening and closing valve in the group of valves 42.

In the substrate processing apparatus 1, a shield 46 is detachably provided along the inner wall surface of the chamber body 12 and the outer periphery of the support 13. The shield 46 keeps reaction byproducts from adhering to the chamber body 12. The shield 46 may be configured, for example, by forming a corrosion-resistant film on the surface of a base material formed from aluminum. The corrosion-resistant film may be formed from a ceramic such as yttrium oxide.

A baffle plate 48 is provided between the support 13 and the side wall of the chamber body 12. The baffle plate 48 may be configured, for example, by forming a corrosion-resistant film (a film such as yttrium oxide) on the surface of a member formed from aluminum. The baffle plate 48 is formed with a plurality of through holes. An exhaust port 12e is provided below the baffle plate 48 in the bottom portion of the chamber body 12. An exhaust device 50 is connected to the exhaust port 12e via an exhaust pipe 52. The exhaust device 50 includes a pressure-regulating valve and a vacuum pump such as a turbo molecular pump.

The substrate processing apparatus 1 includes a high RF power supply 62 and a bias power supply 64. The high RF power supply 62 is a power supply that generates high RF power HF. The high RF power HF has a first frequency suitable for plasma generation. The first frequency may be, for example, a frequency in the range of 27 MHz to 100 MHz. The high RF power supply 62 is connected to the lower electrode 18 via a matching box 66 and the electrode plate 16. The matching box 66 has a circuit for matching the impedance on the load side (lower electrode 18 side) of the high RF power supply 62 with the output impedance of the high RF power supply 62. The high RF power supply 62 may be connected to the upper electrode 30 via the matching box 66. The high RF power supply 62 is an example of a plasma-generator.

The bias power supply 64 is a power supply that generates an electrical bias. The bias power supply 64 is connected electrically to the lower electrode 18. The electrical bias has a second frequency. The second frequency is lower than the first frequency. The second frequency is, for example, a frequency in the range of 400 kHz to 13.56 MHz. When used in combination with high RF power HF, the electrical bias is applied to the substrate support 14 to attract ions toward the substrate W. In one example, the electrical bias is applied to the lower electrode 18. When an electrical bias is applied to the lower electrode 18, the potential of the substrate W mounted on the substrate support 14 fluctuates within a period defined by the second frequency. The electrical bias may be applied to a bias electrode provided in the electrostatic chuck 20.

When plasma processing is performed in the substrate processing apparatus 1, the processing gas is supplied from the gas supply source (group of gas sources 40, gas supply pipe 38, etc.) to the interior space 10s via the gas supply in the upper electrode 30. High RF power HF and/or an electric bias is also supplied to generate a high RF electric field between the upper electrode 30 and the lower electrode 18. The high RF electric field forms plasma from the processing gas in the interior space 10s.

The substrate processing apparatus 1 may also include a power source 70. The power source 70 is connected to the top plate 34 of the upper electrode 30 and the chamber body 12. The power source 70 is configured to supply negative direct current voltage or low RF power to at least one of the upper electrode 30 and the chamber body 12 during plasma processing. Positive ions in the plasma are drawn toward and collide with the upper electrode 30 and/or the chamber body 12 which have negative potential. The direct current voltage or low RF power may be supplied as pulse waves or continuous waves. In one example, the direct current power source 70 may be connected to only one of the top plate 34 of the upper electrode 30 or the chamber body 12 and supply negative direct current voltage to only one of them.

The substrate processing apparatus 1 may also include a controller 80. The controller 80 may be a computer including a processor, a storage such as memory, an input device, a display device, and a signal input/output interface. The controller 80 controls each unit in the substrate processing apparatus 1. The operator can use the input device to issue instructions to the controller 80 in order to manage the substrate processing apparatus 1. The controller 80 can also visually display the operational status of the substrate processing apparatus 1 on the display device. Control programs and recipe data are stored in the storage. The control program is executed by the processor in order to execute various processes in the substrate processing apparatus 1. The processor executes a control program and controls each unit in the substrate processing apparatus 1 according to the recipe data. In one exemplary embodiment, some or all of the controller 80 may be provided as a portion of the configuration of a device external to the substrate processing apparatus 1.

<Configuration of Portions Exposed to Plasma In Chamber 10>

In an example, the portions of the chamber 10 exposed to plasma formed in the interior space 10s are made of a conductive silicon-containing material.

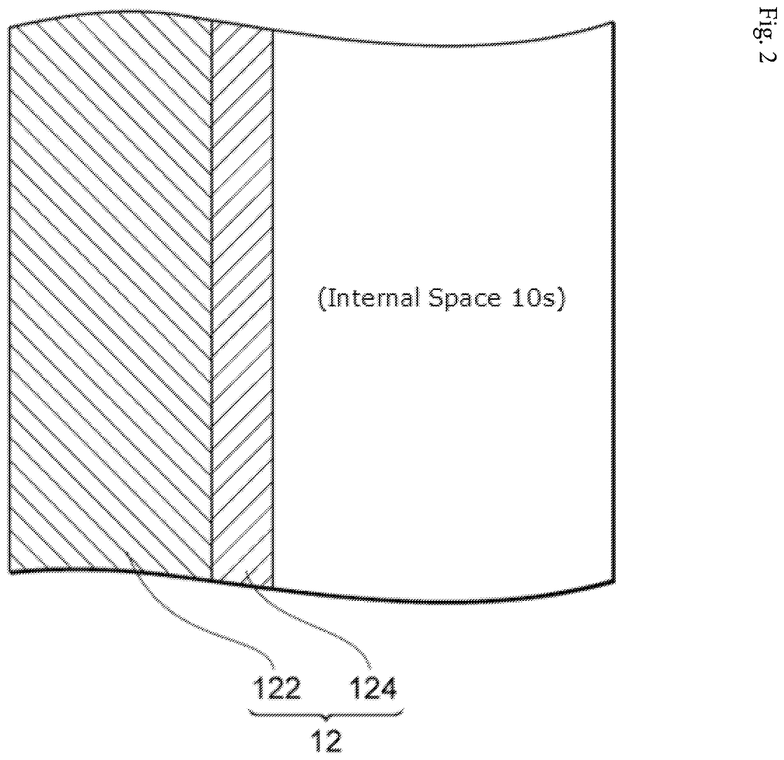

FIG. 2 is a figure explaining an example of the cross-sectional structure of a chamber body 12. As shown in FIG. 2, the chamber body 12 is provided a first layer 122 and a second layer 124 in order from the outside to the inside (that is, the side facing the interior space 10s).

The first layer 122 constitutes the outer wall of the chamber body 12. The first layer 122 is formed from, for example, aluminum. The second layer 124 constitutes the inner wall of the chamber body 12. The second layer 124 is a portion exposed to plasma formed in the interior space 10s. The second layer 124 is formed from a conductive silicon-containing material. The silicon-containing material may be, for example, silicon (single crystal silicon, polycrystalline silicon) or silicon carbide. The thickness of the second layer 124 may be, for example, from 5 mm to 50 mm. The surface of the silicon-containing material constituting the second layer may be coated with carbon.

The second layer 124 may be detachably applied to the first layer 122. For example, the second layer 124 may be configured as a liner (lining) having a shape that covers the inner peripheral surface of the first layer 122, and the liner may be detachably applied to the first layer 122. In one example, the second layer 124 may be integrally formed with the first layer 122. For example, the inner peripheral surface of the first layer 122 may be coated with a silicon-containing material that integrally forms the second layer 124.

The chamber body 12 may have three or more layers, for example, one or more layers made of a material different from that of the first layer 122 and the second layer 124 between the first layer 122 and the second layer 124. The chamber body 12 may be a single layer, and the entire chamber body 12 may be made of a silicon-containing material that is conductive. The inner surface of the chamber body 12 (the side facing the interior space 10s) may be coated with carbon. The lower surface of the top plate 34 of the upper electrode 30 faces the interior space 10s, and is a portion like the second layer of the chamber body 12 that is exposed to plasma. The top plate 34 is made of a conductive silicon-containing material. The top plate 34 may be formed from, for example, silicon (single crystal silicon) or silicon carbide. The material constituting the top plate 34 and the second layer of the chamber body 12 may be the same material or may be different materials. For example, the lower surface of the top plate 34 may be coated with carbon.

In one example, only some of the plasma-exposed portions of the chamber body 12 and the upper electrode 30 may be made of a conductive silicon-containing material. For example, the top plate 34 of the upper electrode 30 may be made of a conductive silicon-containing material, and the chamber body 12 may be formed from aluminum with a corrosion-resistant film such as yttrium oxide formed on its surface. Also, for example, some or all of the inner wall of the chamber body 12 may be a second layer 124 made of a conductive silicon-containing material, and the top plate 34 of the upper electrode 30 may be made of an insulating material such as quartz.

Among the other members in the chamber body 12, those that may be exposed to plasma formed in the interior space 10s, such as the shield 46 and the baffle plate 48, may be made of a conductive silicon material.

<Example of Substrate W>

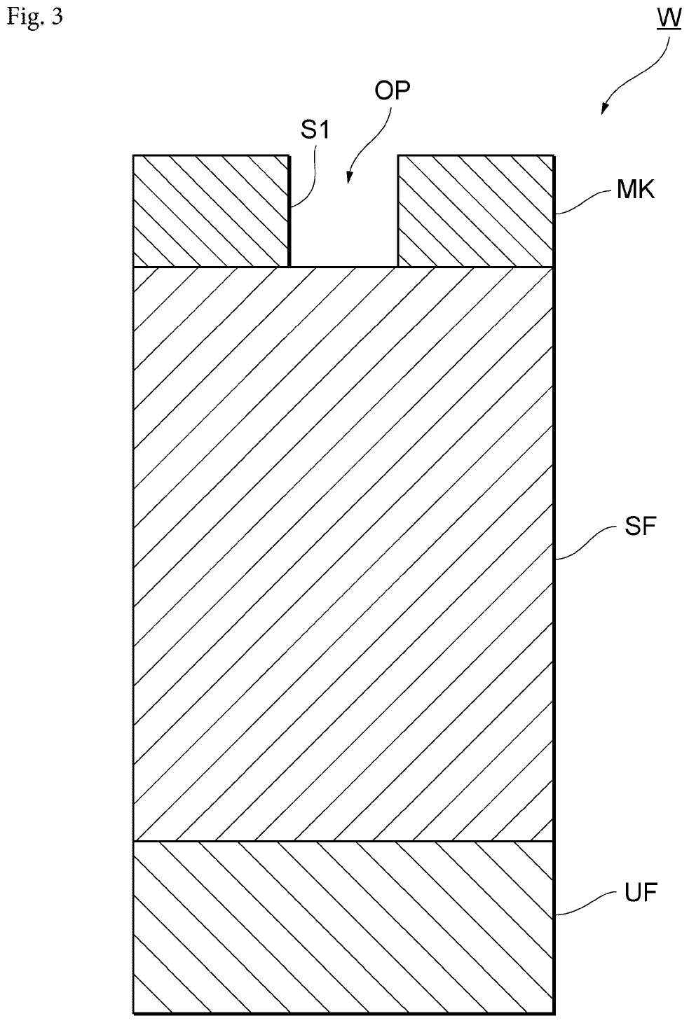

FIG. 3 is a figure showing an example of the cross-sectional structure of a substrate W. The substrate W is an example of a substrate to which the processing method may be applied. The substrate W has a silicon-containing film SF. The substrate W may also have an underlying film UF and a mask film MK. As shown in FIG. 3, the substrate W may be formed by stacking an underlying film UF, a silicon-containing film SF, and a mask film MK in successive order.

The underlying film UF may be, for example, a silicon wafer or an organic film, a dielectric film, a metal film, or a semiconductor film formed on a silicon wafer. The underlying film UF may be composed of a plurality of stacked films.

The silicon-containing film SF may be a silicon oxide film, a silicon nitride film, a silicon acid nitride film (SiON film), or a Si-ARC film. The silicon-containing film SF may include a polycrystalline silicon film. The silicon-containing film SF may be formed by laminating a plurality of films. The silicon oxide film may be a stacked film containing at least two types of film selected from the group consisting of a silicon oxide film, a silicon nitride film, and a polysilicon film. For example, the silicon-containing film SF may be composed of alternately stacked silicon oxide films and polycrystalline silicon films. The silicon-containing film SF may also be configured, for example, by alternately laminating silicon oxide films and silicon nitride films.

The underlying film UF and/or the silicon-containing film SF may be formed using, for example, the CVD method or the spin coating method. The underlying film UF and/or the silicon-containing film SF may be a flat film or may be an uneven film.

The mask film MK is formed on the silicon-containing film SF. The mask film MK defines at least one opening OP in the silicon-containing film SF. The opening OP is a space in the silicon-containing film SF surrounded by side walls S1 of the mask film MK. In other words, in FIG. 3, the silicon-containing film SF has a region covered by the mask film MK and a region exposed at the bottom of the opening OP.

The opening OP may have any shape on the substrate W in the plan view (when the substrate W is viewed looking downward from the top in FIG. 3). The shape may be, for example, a hole shape, a line shape, or a combination of a hole shape and a line shape. The mask film MK may have a plurality of side walls S1, and the plurality of side walls S1 may define a plurality of openings OP. The plurality of openings OP each have a line shape, and may be arranged at regular intervals to form a line-and-space pattern. Also, the plurality of openings OP may have a hole shape and form an array pattern.

The mask film MK is, for example, an organic film or a metal-containing film. The organic film may be, for example, a spin-on-carbon film (SOC), an amorphous carbon film, or a photoresist film. The metal-containing film may contain, for example, tungsten, tungsten carbide, or titanium nitride. The mask film MK may be formed using, for example, the CVD method or the spin coating method. The opening OP may be formed by etching the mask film MK. The mask film MK may be formed by lithography.

<Example of the Processing Method >

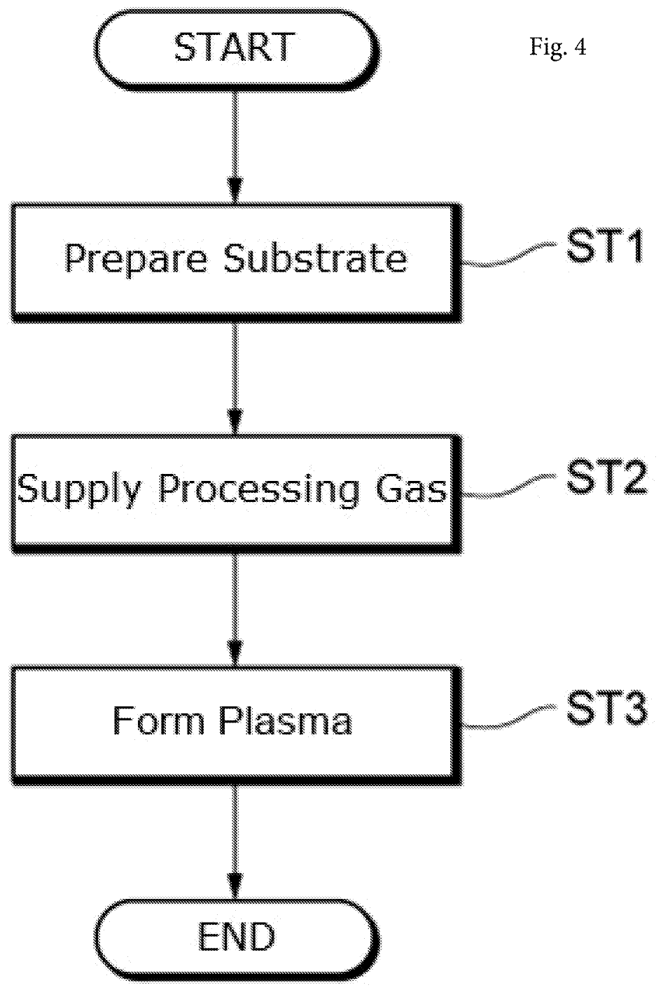

FIG. 4 is a flowchart showing an example of the substrate processing method performed by the substrate processing apparatus 1 (“the processing method” below). In this example of the processing method, plasma is formed by supplying a processing gas into a chamber in which a substrate W has been placed in order to etch the dielectric film DF on the substrate W. The processing method includes a step of preparing a substrate (step ST1), a step of supplying a processing gas (step ST2), and a step of forming plasma (step ST3). Note that step ST2 and step ST3 may be performed concurrently.

An example of the processing method shown in FIG. 4 being executed on the substrate W shown in FIG. 3 will now be described with reference to the drawings. In the following example, the controller 80 shown in FIG. 1 executes the processing method by controlling each unit in the substrate processing apparatus 1.

(Step ST1: Preparation of Substrate)

In step ST1, a substrate W is prepared in the interior space 10s of the chamber 10. The substrate W is placed on the substrate support 14 in the interior space 10s and secured by the electrostatic chuck 20. At least some of the process of forming each configuration on the substrate W may be performed in the interior space 10s. Also, after some or all of each configuration on the substrate W has been formed by an external apparatus or some other chamber in the substrate processing apparatus 1, the substrate W may be transported to the interior space 10s and placed on the substrate support 14.

(Step ST2: Supply Processing Gas)

In step ST2, the processing gas is supplied from the gas supply to the interior space 10s. The processing gas is a gas used to etch the silicon-containing film SF formed on the substrate W.

The processing gas contains HF gas and CₓH_{y}F_{z} gas (where x and z are integers equal to or greater than 1 and y is an integer equal to or greater than 0; “the CF/CHF gas” below) as the reaction gases.

The HF gas may have the highest flow rate relative to the overall flow rate of the reaction gases in the processing gas. The flow rate of the HF gas relative to the overall flow rate of the reaction gases may be, for example, 50 vol % or more, 60 vol % or more, 70 vol % or more, 80 vol % or more, 90 vol % or more, or 95 vol % or more. Also, the flow rate of the HF gas relative to the overall flow rate of the reaction gases may be, for example, less than 100 vol %, 99.5 vol % or less, 98 vol % or less, or 96 vol % or less. In one example, the flow rate of hydrogen fluoride gas is adjusted to 70 vol % or more and 96 vol % or less relative to the overall flow rate of the reaction gases. In the present embodiment, the reaction gases do not include an inert gas such as a noble gas.

Note that instead of some or all of the HF gas, a fluorine-containing gas capable of producing hydrogen fluoride (HF) species in the chamber may be used during plasma processing. These HF species include at least one of hydrogen fluoride gas, radicals, and ions. In one example, the fluorine-containing gas may be a hydrofluorocarbon gas. The fluorine-containing gas may also be a mixed gas containing a source of hydrogen and a source of fluorine. The source of hydrogen may be, for example, H₂, NH₃, H₂O, H₂O₂ or a hydrocarbon (CH₄, C₃H₆, etc.). The source of fluorine may be NF₃, SF₆, WF₆, XeF₂, fluorocarbon, or hydrofluorocarbon.

The CF/CHF gas may be, for example, at least one selected from the group consisting of CF₄ gas, C₃F₈ gas, C₄F₆ gas, C₄F₈ gas, CH₂F₂ gas, CHF₃ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In one example, the CF/CHF gas is at least one selected from the group consisting of C₄H₂F₆ gas, C₄H₂F₈ gas, C₃H₂F₄ gas, and C₃H₂F₆ gas.

The flow rate of the CF/CHF gas relative to the overall flow rate of the reaction gases in the processing gas may be, for example, 1 vol % or more, or 5 vol % or more. The flow rate of the CF/CHF gas may be lower than the flow rate of the HF gas, and may be, for example, 20 vol % or less, 15 vol % or less, or 10 vol % or less relative to the overall flow rate of the reaction gases.

The processing gas used in the processing method may be selected based on the material constituting the silicon-containing film SF, the material constituting the mask film MK, the material constituting the base film UF, the pattern of the mask film MK, the etching depth, and the aspect ratio. For example, the processing gas may also include, as a reaction gas, at least one type selected from the group consisting of phosphorus-containing gases, halogen-containing gases, nitrogen-containing gases, and oxygen-containing gases.

A phosphorus-containing gas protects the side walls of a silicon-containing film SF during etching of the silicon-containing film SF. The phosphorus-containing gas may be at least one type selected from the group consisting of PF₃ gas, PF₅ gas, POF₃ gas, HPF₆ gas, PCI₃ gas, PCI₅ gas, POCI₃ gas, PBr₃ gas, PBr₅ gas, POBr₃ gas, PI₅ gas, P₄O₁₀ gas, P₄O₈ gas, P₄O₆ gas, PH₃ gas, Ca₃P₂ gas, H₃PO₄ gas, and Na₃PO₄ gas. Among these gases, phosphorus halide-containing gases such as PF₃ gas, PF₅ gas, and PCI₃ gas may be used. For example, a phosphorus fluoride-containing gas such as PF₃ gas or PF₅ gas may be used.

A halogen-containing gas may be used to adjust the shape of the mask film MK and a silicon-containing film SF during etching of the silicon-containing film SF. The halogen-containing gas may be a gas containing a halogen element other than fluorine. The halogen-containing gas may be a chlorine-containing gas, a bromine-containing gas and/or an iodine-containing gas. The chlorine-containing gas may be, for example, Cl₂ gas, SiCl₂ gas, SiCl₄ gas, CCl₄ gas, BCl₃ gas, PCI₃ gas, PCI₅ gas, or POCl₃ gas. The bromine-containing gas may be HBr gas, CBr₂F₂ gas, C₂F₅Br gas, PBr₃ gas, PBr₅ gas, or POBr₃ gas. The iodine-containing gas may be HI gas, CF₃I gas, C₂F₅I gas, C₃F₇I gas, IF₅ gas, IFS gas, I₂ gas, or PI₃ gas. In one example, Cl₂ gas and/or HBr gas is used as the halogen-containing gas.

A nitrogen-containing gas may be used to suppress blockage of an opening OP in a mask film MK during etching. The nitrogen-containing gas may be, for example, at least one gas selected from the group consisting of NF₃ gas, N₂ gas, and NH₃ gas.

An oxygen-containing gas, like a nitrogen-containing gas, may be used to suppress blockage of an opening OP in a mask film MK during etching. The oxygen-containing gas may be, for example, at least one gas selected from the group consisting of O₂, CO, CO₂, H₂O, and H₂O₂. In one example, the oxygen-containing gas is a gas other than H₂O, for example, at least one gas selected from the group consisting of O₂, CO, CO₂, and H₂O₂. An oxygen-containing gas causes less damage to a mask film MK and can reduce the amount of morphological deterioration.

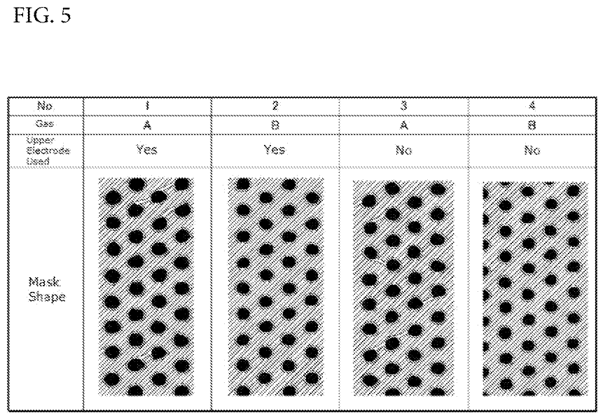

FIG. 5 is a figure showing examples of the shape of mask film MK after etching. FIG. 5 shows examples of the shapes of the mask film MK (plan view) when a sample substrate with the same structure as the substrate W is etched in the substrate processing apparatus 1. In FIG. 5, “No.” indicates the number of the etched sample substrate. “Gas” indicates the processing gas used for etching, and “A” indicates a processing gas containing HF gas, C₄H₂F₆ gas, O₂ gas, NF₃ gas, HBr gas and Cl₂ gas (“processing gas A” below). In processing gas A, the flow rate of HF gas is 80 vol % or more relative to the overall flow rate of the reaction gases, and the flow rate of O₂ gas is 4 to 5 vol % relative to the overall flow rate of the reaction gases. Also, “B” in the “Gas” row indicates the same processing gas as processing gas A except that it does not contain NF₃ gas and the flow rate for the O₂ gas has been increased (“processing gas B” below). In processing gas B, the flow rate for the O₂ gas is 6 to 7 vol % relative to the overall rate of the reaction gases. In the “Upper Electrode Used” row, “Yes” indicates that negative direct current voltage was supplied to the upper electrode 30 of the substrate processing apparatus 1 during etching, and “No” indicates that the negative direct current voltage was not supplied to the upper electrode 30. In the “Mask Shape” row of FIG. 5, it is clear that when processing gas A containing NF₃ was used (Sample 1 and Sample 3), the roundness of the opening OP deteriorated and the surface of the mask film MK was uneven, whether “Upper Electrode Used” was “Yes” or “No.” Meanwhile, when processing gas B is used, which does not contain NF₃ gas and which has an increased flow rate for O₂ gas (Sample 2 and Sample 4), the roundness of the opening OP is good, the mask film MK is not uneven, and the morphology of the mask film MK is better than when processing gas A is used (Sample 1 and Sample 3).

The processing gas may contain, for example, an inert gas (a noble gas such as Ar) in addition to the reaction gases described above.

The pressure of the processing gas supplied to the interior space 10s is adjusted by using a pressure regulating valve in the exhaust device 50 connected to the chamber body 12. The pressure of the processing gas may be, for example, 5 mTorr (0.7 Pa) or more and 100 mTorr (13.3 Pa) or less, 10 mTorr (1.3 Pa) or more and 60 mTorr (8.0 Pa) or less, or 20 mTorr (2.7 Pa) or more and 40 mTorr (5.3 Pa) or less.

(Step ST3: Form Plasma)

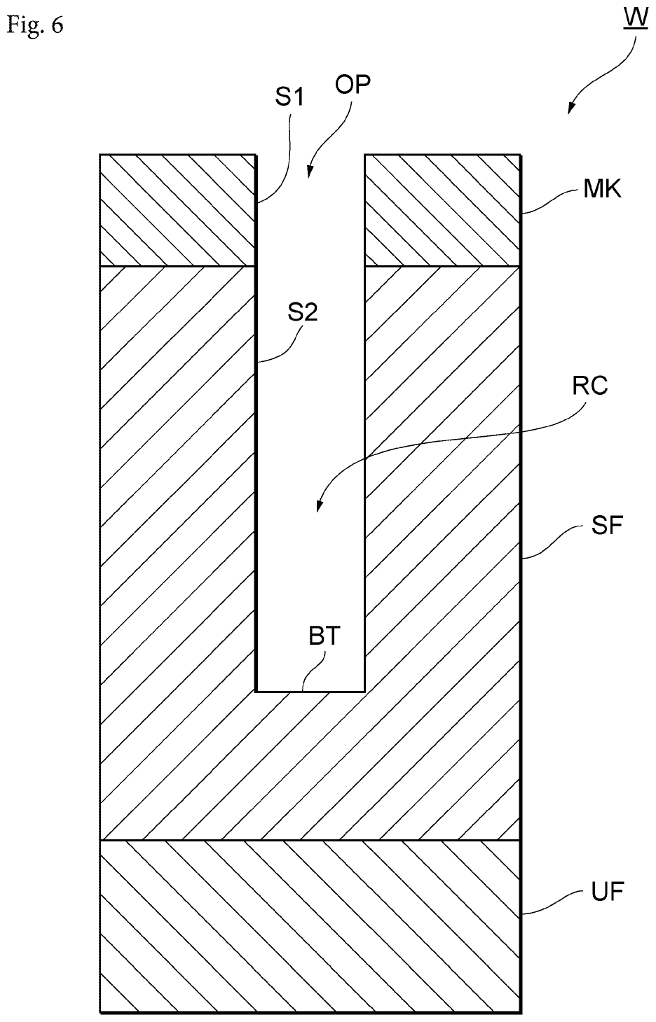

FIG. 6 is a figure showing an example of the cross-sectional structure of a substrate W in step ST3. In step ST3, when high RF power and/or an electric bias is supplied from the plasma-generator (high RF power supply 62 and/or bias power supply 64), a high RF electric field is generated between the upper electrode 30 and the substrate support 14. As a result, plasma is formed from the processing gas supplied to the interior space 10s.

Plasma formed from the HF gas and CF/CHF gas contains HF species. In step ST3, the HF species in the plasma are attracted to the substrate W, react with the silicon in the silicon-containing film SF, and are volatilized as a silicon fluoride compound. In other words, the HF species function as the etchant for the silicon-containing film SF. At this time, the carbon in the CF/CHF gas may deposit carbon on the surface of the mask film MK to protect the surface. In this way, as shown in FIG. 6, a recess RC (such as a hole- or trench-shaped recess) defined by the side walls S2 of the silicon-containing film SF is formed continuously from the opening OP formed in the mask film MK based on the shape of the opening OP in the mask film MK. The aspect ratio of the recess RC may be 20 or more, 30 or more, 40 or more, 50 or more, or 100 or more.

In step ST3, the substrate support 14 may be kept at a low temperature. The adsorption coefficient of HF radicals increases further at low temperatures. Therefore, keeping the substrate support 14 at a low temperature and suppressing any increase in the temperature of the substrate W promotes the adsorption of HF species (etchant) at the bottom BT of the recess RC. This can improve the etching rate of the silicon-containing film SF. The temperature of the substrate support 14 may be, for example, 0° C. or lower, −10° C. or lower, −20° C. or lower, −30° C. or lower, −40° C. or lower, or −70° C. or lower. The temperature of the substrate support 14 may be adjusted using the heat exchange medium supplied from the chiller.

In the present embodiment, among the members constituting the chamber 10 of the substrate processing apparatus 1, those that are exposed to plasma formed in the interior space 10s (the “plasma-exposed portions” below) are made of a conductive silicon-containing material. Examples of the members constituting the chamber 10 include the chamber body 12 and the upper electrode 30. In step ST3, the silicon in the plasma-exposed portions may react with the HF species in the plasma and volatilize from the surface of the plasma-exposed portions as a silicon fluoride compound. In other words, the surface of the plasma-exposed portions may be etched. However, carbon in the CF/CHF gas is deposited on the plasma-exposed portions made of a conductive silicon-containing material in step ST3 to protect the plasma-exposed portions. As a result, damage to the surface of the plasma-exposed portions due to excessive etching and erosion can be prevented. In an experiment conducted by the present inventors, when the plasma-exposed portions were made of quartz instead of a conductive silicon-containing material, the extent of damage to the plasma-exposed portions (quartz) did not improve even if CF/CHF gas was added to a processing gas consisting of HF gas (1 vol % relative to the overall flow rate of the reaction gas). This may be because the carbon in the CF/CHF gas was used up by the reaction with oxygen in the quartz to generate CO, and its protective effect on the plasma-exposed portions was insufficient.

Also, even when the plasma-exposed portions are etched in the present embodiment, a highly volatile silicon fluoride compound is produced as mentioned above. Therefore, the silicon fluoride compound can be easily removed from the interior space 10s after the plasma processing and thereby the increase of particles in the interior space 10s can be reduced.

In step ST3, negative direct current voltage may be supplied from the power source 70 to the upper electrode 30 and the chamber body 12. As a result, the positive ions in the plasma are attracted toward and collide with the upper electrode 30 and/or the chamber body 12, which have a negative potential. As a result, silicon and secondary electrons are emitted from the plasma-exposed portions. Because the surface of the plasma-exposed portions is eroded further, excessive deposition of carbon on the plasma-exposed portions can be suppressed, such as when the flow rate of CF/CHF gas is high. In one example, negative direct current voltage may be supplied only to the upper electrode 30 and the potential of the chamber body 12 kept at 0. Also, negative direct current voltage may be supplied only to the chamber body 12. In one example, the power source 70 may supply low RF power to the upper electrode 30 and/or the chamber body 12 instead of direct current voltage. When oxygen is in the plasma, the released silicon combines with the oxygen and is deposited on the mask MK as a silicon oxide compound, and this may function as a protective film.

The emitted secondary electrons help to improve plasma density. The secondary electrons may also modify the mask film MK to improve the etching resistance of the mask film MK. Exposure to secondary electrons neutralizes the charged state of the substrate W and thus improves the linearity of ions traveling into the recess RC formed during the etching process. As described above, the etching selectivity of the silicon-containing film SF may be improved with respect to the mask film MK, shape abnormalities in the recess RC formed during the etching process may be reduced, and the etching rate may be improved.

### EXAMPLES

The processing method was performed by the substrate processing apparatus 1 on a blanket substrate W that had a photoresist film without an opening, and the composition of the plasma in the interior space 10s ten minutes after forming plasma was measured using a quadrupole mass analyzer.

In Example 1, a top plate 34 made of single-crystal silicon and a chamber body 12 made of yttrium-coated aluminum were used in the substrate processing apparatus 1. The processing gas had a HF gas to C₄H₂F₆ gas flow rate ratio (volume ratio) of 100:1. The temperature of the substrate support 14 while forming plasma was −40° C.

Example 2 was the same as Example 1 except that the HF gas to C₄H₂F₆ gas flow rate ratio was 100:5.

Reference Example 1 was the same as Example 1 except that only HF gas was used as the processing gas.

The results of measuring Example 1, Example 2, and Reference Example 1 using the quadrupole mass analyzer are shown in Table 1. As shown in Table 1, the amount of SiF₃ decreased and the amount of HF increased in Example 1 and Example 2 compared to Reference Example 1. Because SiF₃ is a reaction product produced by the reaction of silicon in the top plate 34 with HF species in the plasma, the decreased amount of SiF₃ means that the reaction between silicon and HF species on the top plate 34 was suppressed. In other words, Example 1 and Example 2 are believed to suppress the reaction silicon and HF species on the top plate 34 and suppress etching (scraping) on the surface of the top plate 34 as compared with Reference Example 1. Also, Example 1 and Example 2 are believed to increase the amount of HF species supplied to the substrate W as compared with Reference Example 1 as a result of suppressing the consumption of HF species on the top plate 34. This may be due to the deposition of carbon on the top plate 34, which protects the surface of the top plate 34, in Example 1 and Example 2, which use a processing gas containing C₄H₂F₆ gas, unlike Reference Example 1, which uses a processing gas that does not contain a CH/CHF gas. In Example 2, which had an increased C₄H₂F₆ flow rate, the amount of SiF₃ in the plasma was lower and the amount of HF was higher than in Example 1. This may be due to more carbon being deposited on the top plate 34 in Example 2 than in Example 1, and the increased surface protecting effect on the top plate 34 as compared with Example 1.

TABLE 1

| | | | Reference |
|---|---|---|---|
| | Example 1 | Example 2 | Example 1 |
| HF (%) | 71 | 76 | 63 |
| SiF₃ (%) | 6 | 2 | 8 |

In an exemplary embodiment, a technique can be provided for suppressing damage caused by plasma.

The embodiments described above are provided for explanatory purposes and should not be interpreted as limiting the scope of the present disclosure. Various modifications of these embodiments are possible without departing from the scope and spirit of the present disclosure.

For example, in the present processing method, a precoat may be formed on the plasma-exposed portions in the chamber 10 prior to step ST1. By forming a precoat prior to plasma processing, excessive erosion (damage) to the surface of the plasma-exposed portions can be suppressed.

The precoat may be a carbon-containing film. In one example, the precoat can be formed by forming plasma from a CF/CHF gas described above. The precoat can be formed, for example, using chemical vapor deposition (CVD) or atomic layer deposition (ALD).

The precoating may be performed every time a substrate W is processed, or may be performed after processing a predetermined number of substrates W or a predetermined number of lots of substrates W. Alternatively, it may be executed after the substrate processing has been performed for a predetermined amount of time.

Also, a substrate processing apparatus using a source of plasma such as inductively coupled plasma or microwave plasma may be used instead of a capacitively coupled substrate processing apparatus 1. At least some of the plasma-exposed portions in the chamber of such a substrate processing apparatus may be made of a conductive silicon-containing material. The substrate processing apparatus may also include a gas supply in a side wall of the chamber.

1. A substrate processing apparatus comprising:
a chamber;
a substrate support disposed in the chamber;
a gas supply disposed in the chamber and connected to a supply source of reaction gas containing HF gas and CₓH_{y}F_{z} gas (where x and z are integers equal to or greater than 1 and y is an integer equal to or greater than 0); and
a plasma-generator configured to form a plasma from the reaction gas supplied to the chamber from the gas supply,
wherein at least a portion of the chamber exposed to the plasma is made of a conductive silicon-containing material.

2. The substrate processing apparatus according to claim 1, wherein the flow rate of the CₓH_{y}F_{z} gas supplied to the chamber is 5 vol % or more relative to the overall flow rate of the reaction gas.

3. The substrate processing apparatus according to claim 1, wherein an inner wall of the chamber is configured by applying a liner made of a conductive silicon-containing material.

4. The substrate processing apparatus according to claim 1, further comprising an upper electrode arranged facing the substrate support, wherein the upper electrode has the gas supply.

5. The substrate processing apparatus according to claim 4, wherein the upper electrode comprises a top plate having a plurality of gas discharge holes for supplying the reaction gas to the chamber, and the top plate is made of a conductive silicon material.

6. The substrate processing apparatus according to claim 1, comprising a power source for supplying negative direct current voltage or low RF power to the chamber.

7. The substrate processing apparatus according to claim 4, comprising a power source for supplying negative direct current voltage or low RF power to the upper electrode.

8. The substrate processing apparatus according to claim 1, wherein a side wall constituting the chamber has the gas supply.

9. A substrate processing method comprising the steps of:
preparing a substrate comprising a silicon-containing film on a substrate support disposed in a chamber;
supplying a reaction gas containing HF gas and CₓH_{y}F_{z} gas (where x and z are integers equal to or greater than 1 and y is an integer equal to or greater than 0) to the chamber; and
forming plasma from the reaction gas supplied to the chamber in order to etch the silicon-containing film,
wherein at least a portion of the chamber exposed to the plasma is made of a conductive silicon-containing material.

10. The substrate processing method according to claim 9, wherein the flow rate of the CₓH_{y}F_{z} gas is 5 vol % or more relative to the overall flow rate of the reaction gas.

11. The substrate processing method according to claim 9, wherein an inner wall of the chamber is configured by applying a liner made of a conductive silicon-containing material.

12. The substrate processing method according to claim 9, wherein negative direct current voltage or low RF power is supplied to the chamber in the step of forming plasma.

13. The substrate processing method according to claim 9, wherein a side wall constituting the chamber has a gas supply that supplies the reaction gas to the chamber.

14. The substrate processing method according to claim 9, wherein an upper electrode arranged facing the substrate support is further provided, the upper electrode having a gas supply that supplies the reaction gas to the chamber.

15. The substrate processing method according to claim 14, wherein the upper electrode comprises a top plate having a plurality of gas discharge holes for supplying the reaction gas to the chamber, and the top plate is made of a conductive silicon material.

16. The substrate processing method according to claim 14, wherein negative direct current voltage or low RF power is supplied to the upper electrode in the step of forming plasma.

17. The substrate processing method according to claim 9, wherein the CₓH_{y}F_{z} gas is at least one type selected from the group consisting of C₄H₂F₆ gas, C₄H₂F₆ gas, C₃H₂F₄ gas, and C₃H₂F₆ gas.

18. The substrate processing method according to claim 9, wherein the reaction gas further comprises at least one type selected from the group consisting of phosphorus-containing gases, halogen-containing gases, oxygen-containing gases, and nitrogen-containing gases.
